(19) United States
(12) Patent Application Publication
(10) Pub. No.: US 2026/0282421 A1
(43) Pub. Date: Sep. 17, 2026

(54) NITRIDE SEMICONDUCTOR DEVICE

(71) Applicant: Panasonic Holdings Corporation, Osaka (JP)

(72) Inventors: MASAHIRO OGAWA, Osaka (JP); SATOSHI TAMURA, Osaka (JP); DAISUKE SHIBATA, Kyoto (JP)

(21) Appl. No.: 19/564,066

(22) Filed: Mar. 11, 2026

(30) Foreign Application Priority Data
Mar. 17, 2025 (JP) 2025-042306

(51) Int. Cl. H10D 30/47; H10D 64/00

(52) U.S. Cl. CPC H10D 30/476; H10D 64/117

(57) ABSTRACT

A nitride semiconductor device includes: a substrate; a gate electrode disposed above the substrate in a first region in plain view of the substrate; a drain electrode disposed below the substrate; a gate electrode pad disposed above the substrate in a second region that does not overlap with the first region in plain view of the substrate; a gate wiring portion disposed above the substrate and electrically connecting the gate electrode pad and the gate electrode; and a conductive film disposed between the drain electrode and at least one of the gate electrode pad and the gate wiring portion.

### BACKGROUND

### Technical Field

The present disclosure relates to a nitride semiconductor device.

### Description of the Related Art

Patent Literature (PTL) 1 discloses a nitride semiconductor device including a 2 dimensional electron gas (2DEG) as a channel. The nitride semiconductor device disclosed in PTL 1 is a so-called vertical transistor. A gate electrode and a source electrode are provided above a substrate, and a drain electrode is provided below the substrate, so that a drain current can flow in a thickness direction of the substrate.

PTL 1: Japanese Patent No. 6511645

### SUMMARY

A nitride semiconductor device according to one aspect of the present disclosure includes: a substrate; a gate electrode disposed above the substrate in a first region in plain view of the substrate; a drain electrode disposed below the substrate; a gate electrode pad disposed above the substrate in a second region that does not overlap with the first region in plain view of the substrate; a gate wiring portion disposed above the substrate and electrically connecting the gate electrode pad and the gate electrode; and a conductive film disposed between the drain electrode and at least one of the gate electrode pad and the gate wiring portion.

### BRIEF DESCRIPTION OF THE DRAWINGS

FIG. 1 is a plan view illustrating a pad configuration of a nitride semiconductor device according to a first exemplary embodiment;

FIG. 2 is a plan view illustrating an electrode configuration of the nitride semiconductor device according to the first exemplary embodiment;

FIG. 3 is a cross-sectional view of the nitride semiconductor device taken along line III-III in FIGS. 1 and 2;

FIG. 4 is a cross-sectional view of the nitride semiconductor device taken along line IV-IV in FIGS. 1 and 2;

FIG. 5 is a cross-sectional view of the nitride semiconductor device taken along line V-V in FIGS. 1 and 2; and

FIG. 6 is a cross-sectional view of a nitride semiconductor device according to a second exemplary embodiment.

### DETAILED DESCRIPTIONS

In the conventional nitride semiconductor device, parasitic capacitance Cgd is generated between the gate and the drain. When parasitic capacitance Cgd increases, a switching loss increases and high-speed operation becomes difficult.

Therefore, the present disclosure provides a nitride semiconductor device capable of reducing a parasitic capacitance between a gate and a drain.

### Summary of Present Disclosure

A nitride semiconductor device according to a first aspect of the present disclosure includes: a substrate; a gate electrode disposed above the substrate in a first region in plan view of the substrate; a drain electrode disposed below the substrate; a gate electrode pad disposed above the substrate in a second region that does not overlap with the first region in plan view of the substrate; a gate wiring portion disposed above the substrate and electrically connecting the gate electrode pad and the gate electrode; and a conductive film disposed between the drain electrode and at least one of the gate electrode pad and the gate wiring portion.

Therefore, electric field lines extending from the drain electrode are shielded by the conductive film, so that parasitic capacitance Cgd between the gate and the drain can be reduced.

A nitride semiconductor device according to a second aspect of the present disclosure is the nitride semiconductor device according to the first aspect, the nitride semiconductor device including: a first nitride semiconductor layer of a first conductivity type disposed above the substrate; a second nitride semiconductor layer of a second conductivity type disposed above the first nitride semiconductor layer, the second conductivity type being opposite in polarity to the first conductivity type; an electron transit layer and an electron supply layer disposed in order from a side of the substrate, the electron transit layer and the electron supply layer covering an inner surface of a first opening that penetrates the second nitride semiconductor layer and reaches the first nitride semiconductor layer and an upper portion of the second nitride semiconductor layer; and a source electrode electrically connected to the electron transit layer, in which the gate electrode is disposed above the electron supply layer.

Therefore, a vertical transistor having a high withstand voltage can be realized.

A nitride semiconductor device according to a third aspect of the present disclosure is the nitride semiconductor device according to the second aspect, in which the conductive film is disposed on the second nitride semiconductor layer.

Therefore, since a reverse bias can be applied to a pn junction between the second nitride semiconductor layer of the second conductivity type (for example, p-type) and the first nitride semiconductor layer of the first conductivity type (for example, n-type), the withstand voltage can be increased.

A nitride semiconductor device according to a fourth aspect of the present disclosure is the nitride semiconductor device according to the second or third aspect, in which the conductive film is electrically connected to the source electrode.

Therefore, the shielding effect of the electric field lines can be enhanced, so that parasitic capacitance Cgd can be reduced.

A nitride semiconductor device according to a fifth aspect of the present disclosure is the nitride semiconductor device according to any one of the first to fourth aspects, in which the conductive film has a length in a wiring width direction of the gate wiring portion, the length being a length of a portion of the conductive film located between the gate wiring portion and the drain electrode, and being longer than a wiring width of the gate wiring portion in plan view of the substrate.

Therefore, since the gate wiring portion and the drain electrode can be prevented from facing each other without the conductive film interposed therebetween, parasitic capacitance Cgd can be reduced.

A nitride semiconductor device according to a sixth aspect of the present disclosure is the nitride semiconductor device according to any one of the first to fifth aspects, in which the conductive film includes a metal film including a metal as a main component.

Therefore, the shielding effect of the electric field lines can be enhanced, so that parasitic capacitance Cgd can be reduced.

A nitride semiconductor device according to a seventh aspect of the present disclosure is the nitride semiconductor device according to the sixth aspect, in which the metal is one selected from a group consisting of Ti, Al, Ni, Pd, Pt, Au, and Cr.

Therefore, the shielding effect of the electric field lines can be enhanced, so that parasitic capacitance Cgd can be reduced.

A nitride semiconductor device according to an eighth aspect of the present disclosure is the nitride semiconductor device according to the second or third aspect, in which the gate electrode is disposed at a position overlapping the first opening in plain view of the substrate.

Therefore, it is possible to control on and off of a transistor in a portion along the inner surface of the first opening.

A nitride semiconductor device according to a ninth aspect of the present disclosure is the nitride semiconductor device according to the second or third aspect, and includes a shielding electrode disposed at a position overlapping the first opening in plain view of the substrate and electrically connected to the source electrode, in which the gate electrode is disposed at a position overlapping the second nitride semiconductor layer without overlapping the first opening in plain view of the substrate.

Therefore, since the shielding electrode can terminate the electric field lines extending from the drain electrode, the parasitic capacitance between the gate and the drain can be reduced.

A nitride semiconductor device according to a tenth aspect of the present disclosure is the nitride semiconductor device according to the second or third aspect and includes a third nitride semiconductor layer of the second conductivity type provided between the electron supply layer and the gate electrode.

Therefore, the potential of a conduction band end of a channel can be increased by the third nitride semiconductor layer of the second conductivity type (for example, p-type), and a threshold value of the transistor can be increased. Therefore, normally-off of the transistor can be easily realized.

Hereinafter, exemplary embodiments will be specifically described with reference to the drawings.

Note that the exemplary embodiments described hereinafter provide comprehensive or specific examples. Numerical values, shapes, materials, constituent elements, arrangement positions and connection forms of the constituent elements, steps, order of the steps, and the like illustrated in the following exemplary embodiments are just an example and are not intended to limit the present disclosure. Furthermore, among the constituent elements in the following exemplary embodiments, constituent elements not recited in independent claims are explained as arbitrary constituent elements.

Furthermore, each of the drawings is a schematic diagram, and is not necessarily strictly illustrated. Thus, scales and the like do not necessarily coincide in the respective drawings, for example. Furthermore, each of the drawings denotes substantially the same configurations with the same reference signs, and duplicated description will not be described or will be simplified.

Furthermore, in the present specification, a term indicating a relationship between elements such as parallel and orthogonal, a term indicating the shape of an element such as rectangular, and a numerical range not only mean strict meanings but also include a substantially equivalent range, for example, a difference of a few percent.

Furthermore, in the present specification, a “thickness direction” of a substrate refers to a direction perpendicular to a principal surface of the substrate. The thickness direction aligns with a stacked direction of semiconductor layers and is also referred to as a “vertical direction”. Furthermore, a direction parallel to the principal surface of the substrate may be referred to as “horizontal direction”. A “vertical” semiconductor device means a device in which a main path of a current such as a drain current or a forward current is provided in the vertical direction, that is, a device in which a main current passes through the substrate in the vertical direction. A “horizontal” semiconductor device means a device in which the main path of a current such as a drain current or a forward current is provided in the horizontal direction, that is, a device in which the main current does not pass through the substrate.

Furthermore, a side on which a heterostructure that generates the 2DEG is provided with respect to the substrate is regarded as “above” or “upper side”, and an opposite side thereof is regarded as “below” or “lower side”. Note that, in the present specification, the terms “above” and “below” do not refer to an upward direction (vertically upward) or a downward direction (vertically downward) in absolute space recognition but are used as terms defined by a relative positional relationship on the basis of a stacking order in a stacking configuration. Furthermore, the terms “above” and “below” are not only applied to a case where two constituent elements are spaced apart from each other and another constituent element is present between the two constituent elements but are also applied to a case where two constituent elements are disposed in close contact with each other and are adjacent to each other.

Furthermore, in the present specification and the drawings, an x-axis, a y-axis, and a z-axis indicate three axes of a three-dimensional orthogonal coordinate system. The z-axis is an axis extending in a direction perpendicular to the principal surface of the substrate. A positive direction of the z-axis corresponds to "above", and a negative direction of the z-axis corresponds to "below". A direction parallel to the z-axis may be referred to as a thickness direction or a stacking direction. The x-axis is an axis extending in a gate length direction, and the y-axis is an axis extending in a gate width direction.

Furthermore, in the present specification, unless otherwise specified, “plan view” refers to when viewed from a direction perpendicular to the principal surface of the substrate of the semiconductor device, that is, when the principal surface of the substrate is viewed from the front.

Furthermore, in the present specification, “A and B overlap in plain view” means that at least a part of A and at least a part of B overlap. That is, a case where only a part of A and only a part of B overlap, a case where the entire A overlaps B, a case where the entire B overlaps A, and a case where A and B completely overlap each other are included.

Furthermore, an n-type and a p-type indicate conductivity types of a semiconductor, and are conductivity types having opposite polarities to each other. The n-type is an example of a first conductivity type, and the p-type is an example of a second conductivity type. An n⁺-type represents a state in which an n-type dopant is added to a semiconductor at a high concentration, that is, a so-called heavy dope. Furthermore, an n⁻-type represents a state in which an n-type dopant is added to a semiconductor at a low concentration, that is, so-called light dope. The n⁺-type and the n⁻-type are each an example of the n-type and may be described as the n-type without being distinguished from each other. Furthermore, the same applies to the p-type, a p⁺-type, and a p⁻-type. As the n-type dopant for the nitride semiconductor, Si, Ge, and the like are used. As the p-type dopant for the nitride semiconductor, Mg, Be, and the like are used.

Furthermore, in the present specification, the “main component” means a component having the highest content rate among all the components constituting a member. For example, a component having a content rate of more than or equal to 50% is a main component. The component is a material, an element, a compound, or the like.

Furthermore, in the present specification, AlGaN represents ternary mixed crystal AlₓGa₁₋ₓN (0 < x < 1). Hereinafter, a multicomponent mixed crystal is abbreviated as an arrangement of constituent element symbols, such as AlInN, GaInN, or the like. For example, AlₓGa_{1-x-y}In_{y}N (0 < x < 1, 0 < y < 1, and 0 < x + y < 1), which is an example of a nitride semiconductor, is abbreviated as AlGaInN. Composition ratios of Al, Ga, and In are represented by x, 1-x-y, and y, respectively.

Furthermore, in the present specification, ordinal numbers such as “first” and “second” do not mean the number or order of constituent elements unless otherwise specified but are used for the purpose of avoiding confusion and distinguishing the same kind of constituent elements.

### First Exemplary Embodiment

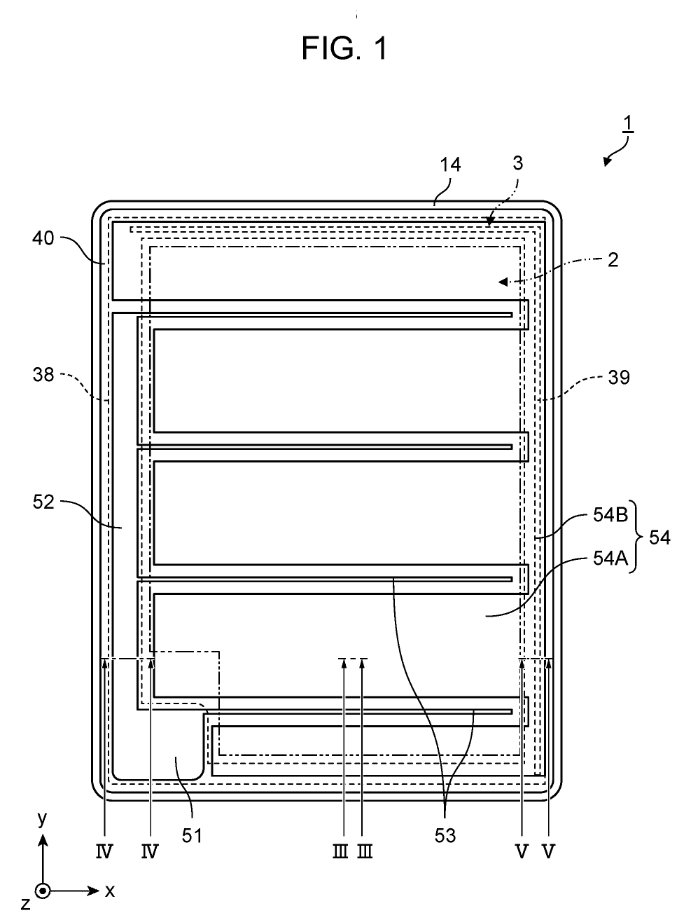

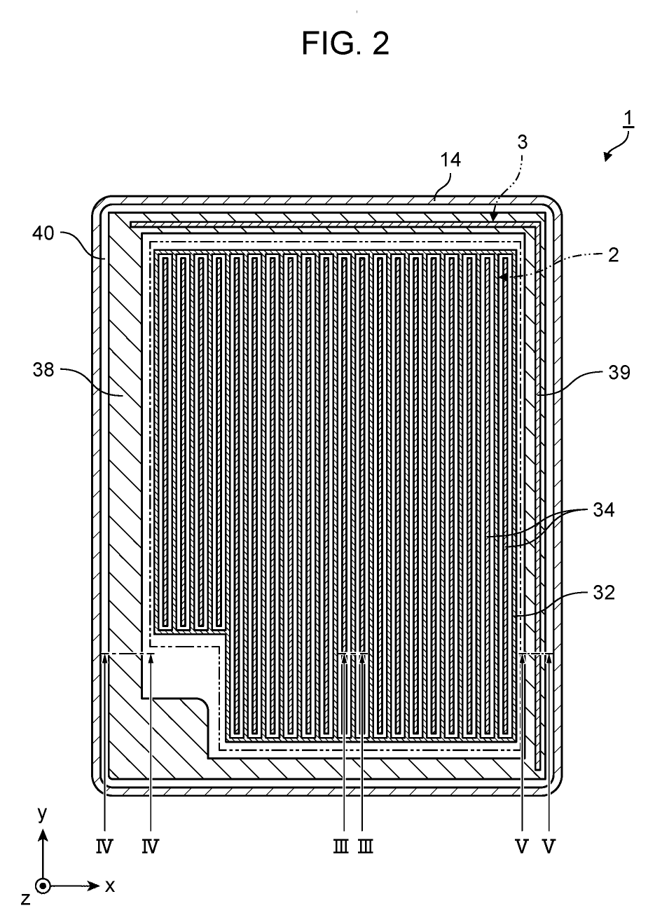

FIG. 1 is a plan view illustrating a pad configuration of nitride semiconductor device 1 according to the present exemplary embodiment. FIG. 2 is a plan view illustrating an electrode configuration of nitride semiconductor device 1 according to the present exemplary embodiment. Note that FIG. 2 illustrates a plan view of nitride semiconductor device 1 when gate electrode pad 51, gate wiring portion 52, gate finger 53, and source wiring 54 in FIG. 1 are removed, and nitride semiconductor device 1 is seen through interlayer insulating film 40. Note that illustration of threshold value adjustment layer 28 is omitted.

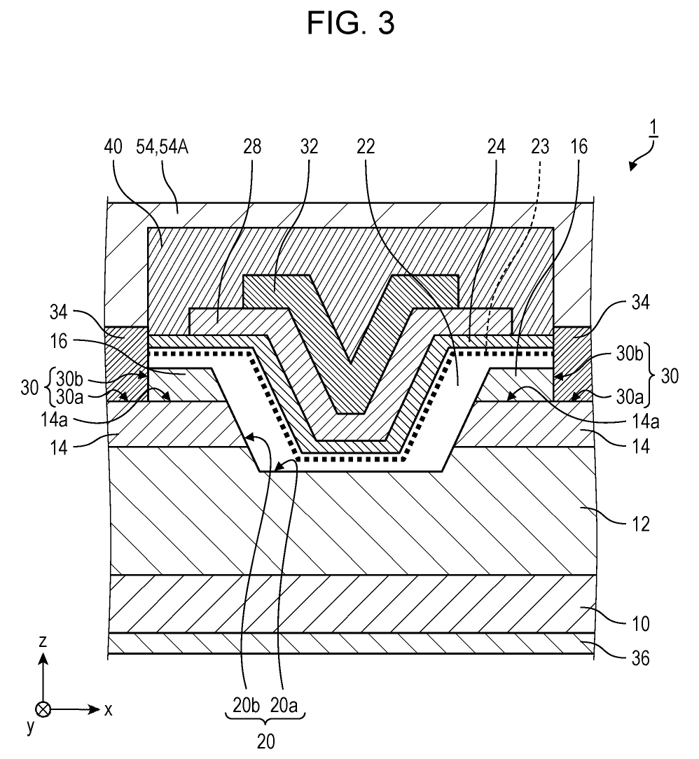

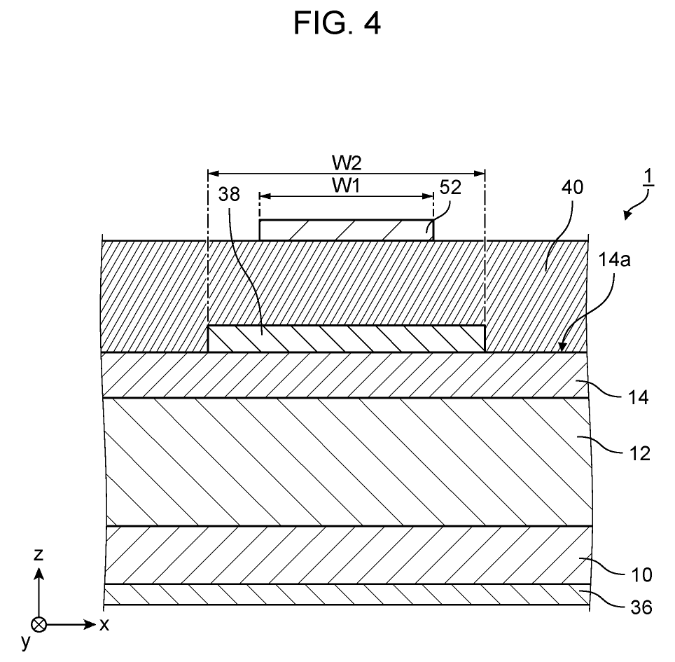

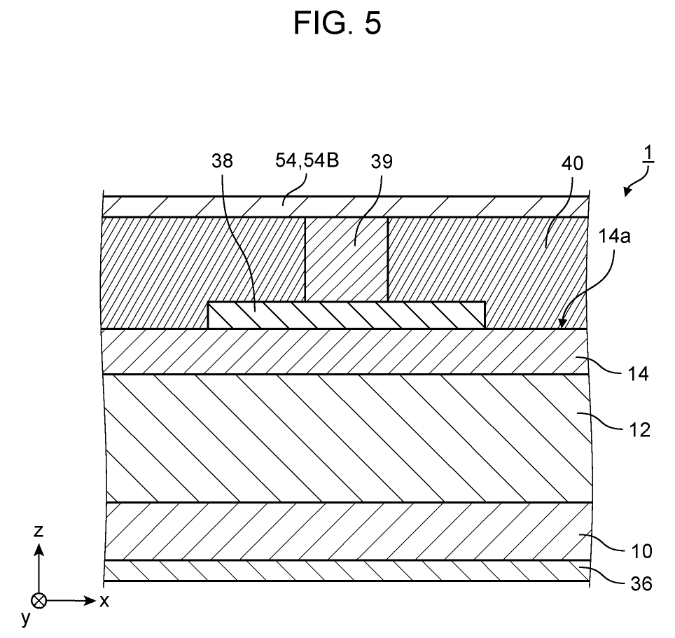

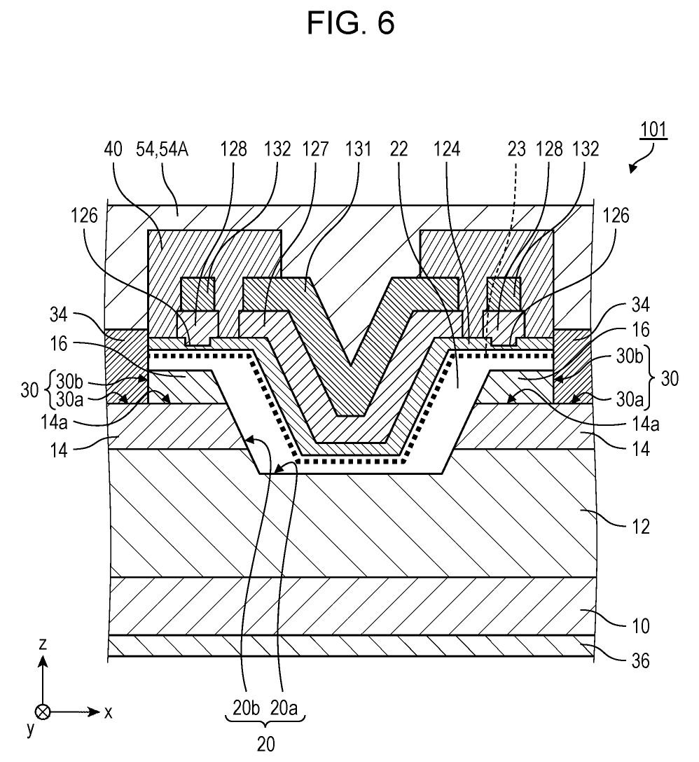

FIG. 3 is a cross-sectional view of nitride semiconductor device 1 taken along line III-III in FIGS. 1 and 2. FIG. 4 is a cross-sectional view of nitride semiconductor device 1 taken along line IV-IV in FIGS. 1 and 2. FIG. 5 is a cross-sectional view of nitride semiconductor device 1 taken along line V-V in FIGS. 1 and 2. In FIGS. 3 to 5, constituent elements such as a semiconductor layer, an insulating layer, and an electrode included in nitride semiconductor device 1 are shaded with diagonal lines representing a cross section. Note that shaded diagonal lines are omitted for electron transit layer 22 illustrated in FIG. 3. The same applies to FIG. 6 described later.

Nitride semiconductor device 1 is a normally-off type vertical field effect transistor (FET). In nitride semiconductor device 1, for example, source electrode 34 is grounded, and a positive potential is applied to drain electrode 36. The potential applied to drain electrode 36 is, for example, between 100V and 1200V inclusive, but is not limited thereto. In nitride semiconductor device 1, a modulation operation according to the potential applied to gate electrode 32 is performed. For example, in a case where 0V or a negative potential (for example, -5V) is applied to gate electrode 32, no current flows between drain electrode 36 and source electrode 34. That is, nitride semiconductor device 1 goes into a non-conductive state (OFF). When a positive potential (for example, +5V) is applied to gate electrode 32, a current flows from drain electrode 36 to source electrode 34. That is, nitride semiconductor device 1 goes into a conductive state (ON). The current flowing from drain electrode 36 to source electrode 34 when ON is referred to as drain current. The drain current flows through substrate 10 in a thickness direction (that is, in a vertical direction).

As illustrated in FIGS. 1 and 2, nitride semiconductor device 1 includes active region 2 and peripheral region 3. Peripheral region 3 is a region that does not overlap with active region 2 in plain view of substrate 10. A two-dot chain line illustrated in FIGS. 1 and 2 represents a boundary line between active region 2 and peripheral region 3. The inside of the two-dot chain line is active region 2, and the outside is peripheral region 3.

Active region 2 is an example of a first region and is a main region of nitride semiconductor device 1. Most of a drain current flow in active region 2 at the time of ON. Active region 2 may be referred to as a device region or an active region. As illustrated in FIG. 2, the plan view shape of active region 2 is substantially the same as the outer shape of gate electrode 32. In active region 2, gate electrode 32, source electrode 34, and the like are provided.

Peripheral region 3 is an example of a second region, and is a region provided around active region 2. In the present exemplary embodiment, peripheral region 3 is annularly provided so as to surround active region 2. Peripheral region 3 may be referred to as an element isolation region or an inactive region. As illustrated in FIG. 1, gate electrode pad 51, gate wiring portion 52, conductive film 38, and the like are provided in peripheral region 3. Note that peripheral region 3 does not need to surround active region 2, and may be provided along one side, two sides, or three sides of approximately rectangular active region 2. Furthermore, for example, peripheral region 3 may be provided separately along two opposing sides of active region 2.

Hereinafter, first, a specific cross-sectional configuration of active region 2 will be described with reference to FIG. 3. As illustrated in FIG. 3, nitride semiconductor device 1 includes substrate 10, drift layer 12, block layer 14, base layer 16, electron transit layer 22, electron supply layer 24, threshold value adjustment layer 28, gate electrode 32, source electrode 34, and drain electrode 36. Furthermore, nitride semiconductor device 1 includes interlayer insulating film 40 and source wiring 54. Furthermore, nitride semiconductor device 1 is provided with first opening 20 and second opening 30. Note that second opening 30 and source electrode 34 are provided on both left and right sides of first opening 20 in cross-sectional view illustrated in FIG. 3.

Note that substrate 10, drift layer 12, block layer 14, interlayer insulating film 40, and source wiring 54 are provided not only in active region 2 but also in peripheral region 3. Furthermore, as illustrated in FIG. 1, active region 2 is provided with gate finger 53 extending from gate wiring portion 52.

Nitride semiconductor device 1 is a device in which a semiconductor layer including a channel includes a nitride semiconductor as a main component. Specifically, each of drift layer 12, block layer 14, base layer 16, electron transit layer 22, electron supply layer 24, and threshold value adjustment layer 28 includes a nitride semiconductor as a main component.

Substrate 10 is, for example, a substrate having a thickness of 300 μm, having a carrier concentration of 5 × 10¹⁸ cm⁻³ and containing n⁺-type GaN as a main component.

Note that substrate 10 may not be a nitride semiconductor substrate. For example, substrate 10 may be a Si substrate, a SiC substrate, a ZnO substrate, or the like.

Drift layer 12 is an example of an n-type first nitride semiconductor layer and is provided above substrate 10. Drift layer 12 is, for example, a film including n⁻-type GaN having a thickness of 8μm as a main component. A donor concentration of drift layer 12 is, for example, between 1 × 10¹⁵ cm⁻³ and 1 × 10¹⁷ cm⁻³ inclusive, and is, as an example, 1 × 10¹⁶ cm⁻³. Furthermore, the carbon concentration (C concentration) of drift layer 12 is, for example, between 1 × 10¹⁵ cm⁻³ and 5 × 10¹⁶ cm⁻³ inclusive. Drift layer 12 is provided, for example, in contact with an upper surface (principal surface) of substrate 10.

Block layer 14 is an example of a p-type second nitride semiconductor layer and is provided above drift layer 12. Block layer 14 is, for example, a film including, as a main component, p-type GaN having a thickness of 400nm and a carrier concentration of 1 × 10¹⁷ cm⁻³. Block layer 14 is provided in contact with an upper surface of drift layer 12.

Base layer 16 is an example of a nitride semiconductor layer and is provided above block layer 14. Base layer 16 is a high-resistance layer having higher resistance than block layer 14. Base layer 16 is, for example, a layer including i-type GaN having a thickness of 200nm as a main component. Base layer 16 is provided in contact with upper surface 14a of block layer 14.

Base layer 16 is an undoped nitride semiconductor layer but may be an insulating layer or a semi-insulating layer. Base layer 16 may be doped with carbon. For example, the carbon concentration of base layer 16 is higher than the carbon concentration of block layer 14. For example, the carbon concentration of base layer 16 is 3 × 10¹⁷ cm⁻³ or more but may be 1 × 10¹⁸ cm⁻³ or more. At this time, each concentration of silicon (Si) or oxygen (O) to be the n-type impurity is lower than the carbon concentration. For example, the silicon concentration or the oxygen concentration of base layer 16 is 5 × 10¹⁶ cm⁻³ or less but may be 2 × 10¹⁶ cm⁻³ or less. As the type of ions to be injected into base layer 16, ion species other than the above ion species can provide the same effect as long as the ion species can increase the resistance of the semiconductor layer. Note that base layer 16 may not be provided.

Block layer 14 and base layer 16 are provided with first opening 20. First opening 20 penetrates base layer 16 and block layer 14 and reaches drift layer 12. First opening 20 may be referred to as a gate opening or a vertical conduction opening. Bottom surface 20a of first opening 20 is a part of drift layer 12. As illustrated in FIG. 3, bottom surface 20a is located on a lower side than the lower surface of block layer 14. Bottom surface 20a is, for example, parallel to the principal surface of substrate 10. When nitride semiconductor device 1 is ON, a drain current flows between drain electrode 36 and source electrode 34 through bottom surface 20a of this first opening 20.

In the present exemplary embodiment, first opening 20 is formed such that an opening area increases with increasing distance from substrate 10. Specifically, side surface 20b of first opening 20 is inclined obliquely. As illustrated in FIG. 3, the cross-sectional view shape of first opening 20 is an inverted trapezoid, more specifically, an inverted isosceles trapezoid.

An inclination angle of side surface 20b with respect to bottom surface 20a is, for example, between 20° and 80° inclusive, but may be between 30° and 45° inclusive. Since side surface 20b approaches a c-plane as the inclination angle decreases, the film quality of electron transit layer 22 and the like formed alongside surface 20b by crystal regrowth can be improved. On the other hand, as the inclination angle is larger, first opening 20 is more prevented from becoming too large, and miniaturization of nitride semiconductor device 1 is realized. Note that side surface 20b may form a right angle with respect to bottom surface 20a.

Electron transit layer 22 is provided above substrate 10. Specifically, electron transit layer 22 is an example of a first regrowth layer and is provided so as to cover the inner surface of first opening 20 and above block layer 14. For example, a part of electron transit layer 22 is provided along bottom surface 20a and side surface 20b of first opening 20, and the other part of electron transit layer 22 is provided on the upper surface of base layer 16. A thickness of electron transit layer 22 is, for example, 50nm or more and 300nm or less. Electron transit layer 22 is, for example, a film having a thickness of 150nm and including undoped GaN as a main component. Note that the thickness of electron transit layer 22 is regarded as the thickness outside first opening 20 in plain view of substrate 10, specifically, the thickness at a flat portion that is a portion overlapping upper surface 14a of block layer 14. Furthermore, electron transit layer 22 is assumed to be undoped, but may be partially made into an n-type by Si doping or the like.

Electron transit layer 22 is in contact with drift layer 12 on bottom surface 20a and side surface 20b of first opening 20. Furthermore, electron transit layer 22 is in contact with block layer 14 on side surface 20b of first opening 20. Specifically, electron transit layer 22 is in contact with the upper surface of base layer 16.

Electron transit layer 22 includes a channel. Specifically, 2DEG 23 serving as a channel is generated in the vicinity of an interface between electron transit layer 22 and electron supply layer 24. 2DEG 23 is bent along the interface between electron transit layer 22 and electron supply layer 24, that is, along the inner surface of first opening 20.

Although not illustrated in FIG. 1, an AlN layer having a thickness of about 1nm is provided as a second regrowth layer between electron transit layer 22 and electron supply layer 24. Therefore, alloy scattering is suppressed, channel mobility is improved, and on-resistance can be reduced. Note that the AlN layer is not necessarily required.

Electron supply layer 24 is provided above electron transit layer 22. That is, electron transit layer 22 and electron supply layer 24 are provided in this order from substrate 10 side. Specifically, electron supply layer 24 is an example of a third regrowth layer and is provided so as to cover the inner surface of first opening 20 and an upper portion of block layer 14. Specifically, electron supply layer 24 is provided along an upper surface of electron transit layer 22 so as to overlap bottom surface 20a and side surface 20b of first opening 20 and upper surface of base layer 16 in plain view of substrate 10.

Electron supply layer 24 has a band gap larger than that of electron transit layer 22. For example, electron supply layer 24 is a film including undoped AlGaN as a main component. Thus, a hetero interface of AlGaN and GaN is formed between electron supply layer 24 and electron transit layer 22. Electron supply layer 24 supplies electrons to the channel (2DEG 23) formed in electron transit layer 22.

Electron supply layer 24 is, for example, a film including undoped AlGaN as a main component. Electron supply layer 24 is formed in a shape along the upper surface of electron transit layer 22 and has a substantially uniform thickness. Note that the thickness of electron supply layer 24 is regarded as the thickness on the outer side of first opening 20 in plain view of substrate 10, that is, at a flat portion that is a portion overlapping the upper surface of base layer 16.

Note that, in a case where electron supply layer 24 includes AlGaN having an Al composition ratio of 20% as a main component, cracks are likely to occur when the thickness of electron supply layer 24 exceeds 70nm. For this reason, the film quality of electron supply layer 24 deteriorates, which may cause leakage, or 2DEG 23 may not be generated at a desired concentration. In a case where the Al composition ratio is lowered, generation of cracks can be suppressed, so that the thickness of electron supply layer 24 can be set to, for example, between 10nm and 150nm inclusive. The Al composition ratio of electron supply layer 24 is not particularly limited, but is, for example, between 10% and 30% inclusive.

Threshold value adjustment layer 28 is an example of a p-type third nitride semiconductor layer and is provided between gate electrode 32 and electron supply layer 24. Threshold value adjustment layer 28 overlaps first opening 20 in plain view of substrate 10 and is electrically connected to gate electrode 32. Specifically, threshold value adjustment layer 28 covers the upper surface of electron supply layer 24 in contact therewith.

Threshold value adjustment layer 28 is, for example, a film containing p-type GaN having a thickness of 50nm and a carrier concentration of 5 × 10¹⁷ cm⁻³ as a main component. The thickness of threshold value adjustment layer 28 is, for example, 10nm or more and 500nm or less. Note that the thickness and carrier concentration of threshold value adjustment layer 28 are merely examples and can be changed as appropriate. For example, threshold value adjustment layer 28 may be a film including p-type AlGaN as a main component.

Second opening 30 penetrates electron supply layer 24, electron transit layer 22, and base layer 16 and reaches block layer 14. Second opening 30 may be referred to as source opening. Second opening 30 is provided at a position away from both gate electrode 32 and threshold value adjustment layer 28 in plan view of substrate 10. Since second opening 30 penetrates electron transit layer 22, 2DEG 23 is exposed on side surface 30b of second opening 30.

Bottom surface 30a of second opening 30 is a part of block layer 14. Bottom surface 30a is, for example, parallel to the principal surface of substrate 10. In the example illustrated in FIG. 3, bottom surface 30a is flush with the lower surface of base layer 16, but the present disclosure is not limited thereto. Bottom surface 30a is located on a lower side than the lower surface of base layer 16.

Furthermore, in the example illustrated in FIG. 3, side surface 30b of second opening 30 is perpendicular to bottom surface 30a, but the present disclosure is not limited thereto. Side surface 30b may be inclined obliquely with respect to bottom surface 30a. That is, second opening 30 may be formed such that the opening area increases as the distance from substrate 10 increases. At this time, an inclination angle of side surface 30b with respect to bottom surface 30a is, for example, in a range from 30° to 60° inclusive. Since side surface 30b is inclined obliquely, a contact area between source electrode 34 and 2DEG 23 increases, so that ohmic connection is easily performed. Note that 2DEG 23 is exposed to side surface 30b of second opening 30 and is connected to source electrode 34 at an exposed portion.

Since second opening 30 is provided, ohmic contact resistance between 2DEG 23 functioning as a channel and source electrode 34 can be reduced. That is, the on resistance of nitride semiconductor device 1 can be reduced.

Furthermore, source electrode 34 and block layer 14 are electrically connected to each other at bottom surface 30a of second opening 30. Therefore, the same potential as a potential applied to source electrode 34 is supplied to block layer 14. In a case where a reverse voltage is applied to the pn junction formed by block layer 14 and drift layer 12, specifically, in a case where drain electrode 36 has a higher potential than source electrode 34, a depletion layer extends to drift layer 12, and thus, the withstand voltage of nitride semiconductor device 1 can be increased.

Gate electrode 32 is provided above substrate 10 in active region 2. Specifically, gate electrode 32 is provided above threshold value adjustment layer 28. More specifically, gate electrode 32 is provided in contact with the upper surface of threshold value adjustment layer 28 and is electrically connected to threshold value adjustment layer 28. Gate electrode 32 is provided at a position overlapping first opening 20 in plain view of substrate 10. Specifically, gate electrode 32 overlaps bottom surface 20a and side surface 20b of first opening 20 in plain view of substrate 10.

Gate electrode 32 is formed using, for example, a conductive material such as metal. For example, gate electrode 32 may be made of a material to be ohmic-connected to a p-type nitride semiconductor such as p-type GaN, but the gate electrode is not limited to this example and may be made of a material to be Schottky connected to the p-type nitride semiconductor. For example, Pd, a Ni-based material, WSi, Au, or the like can be used as a material for forming gate electrode 32.

Source electrode 34 is provided above block layer 14. In the present exemplary embodiment, source electrode 34 is electrically connected to block layer 14 via second opening 30. Furthermore, source electrode 34 is electrically connected to electron transit layer 22 via second opening 30. Specifically, source electrode 34 is provided in contact with bottom surface 30a and side surface 30b of second opening 30. Source electrode 34 is in contact with block layer 14 at bottom surface 30a of second opening 30. Source electrode 34 is in contact with 2DEG 23 on side surface 30b of second opening 30. Therefore, the contact resistance between source electrode 34 and 2DEG 23 can be reduced, so that the on-resistance of nitride semiconductor device 1 can be reduced.

Source electrode 34 is formed using a conductive material such as metal. As the material of source electrode 34, for example, a material to be ohmic-connected to an n-type nitride semiconductor such as n-type GaN through heat treatment, such as Ti/Al (stacked structure of Ti layer and Al layer), can be used.

Drain electrode 36 is provided below substrate 10. Specifically, drain electrode 36 is provided in contact with the lower surface of substrate 10.

Drain electrode 36 is formed using a conductive material such as metal. As the material of drain electrode 36, similarly to the material of source electrode 34, for example, a material such as Ti/Al to be ohmic-connected to an n-type nitride semiconductor such as n-type GaN can be used.

Next, a specific cross-sectional configuration of peripheral region 3 will be described with reference to FIGS. 4 and 5 while appropriately referring to FIGS. 1 to 3. FIG. 4 illustrates a cross section of a portion where gate wiring portion 52 is provided. As illustrated in FIG. 4, nitride semiconductor device 1 includes substrate 10, drift layer 12, block layer 14, conductive film 38, interlayer insulating film 40, and gate wiring portion 52 in peripheral region 3. Furthermore, as illustrated in FIG. 1, nitride semiconductor device 1 includes gate electrode pad 51. A cross-sectional view of a portion where gate electrode pad 51 is provided is also similar to FIG. 4. Furthermore, as illustrated in FIG. 5, nitride semiconductor device 1 includes conductive via 39 and connection portion 54B that is a part of source wiring 54.

Interlayer insulating film 40 is provided above gate electrode 32 and conductive film 38. Specifically, in active region 2, interlayer insulating film 40 is provided so as to cover gate electrode 32, threshold value adjustment layer 28, electron supply layer 24, and source electrode 34 as illustrated in FIG. 3. As illustrated in FIGS. 4 and 5, interlayer insulating film 40 is provided so as to cover conductive film 38 and block layer 14 in peripheral region 3.

Interlayer insulating film 40 has a stacked structure of a plurality of insulating films. The plurality of insulating films is, for example, insulating films of SiN, SiO₂, SiON, Al₂O₃, or the like. Note that interlayer insulating film 40 may have a single-layer structure of one insulating film.

Gate electrode pad 51 is provided above substrate 10 in peripheral region 3 in plan view of substrate 10. Specifically, gate electrode pad 51 is provided on interlayer insulating film 40. Gate electrode pad 51 is a conductive portion that receives power to be supplied to gate electrode 32 from the outside of nitride semiconductor device 1. A bonding wire (not illustrated) or the like is connected to gate electrode pad 51. As illustrated in FIG. 1, gate electrode pad 51 is provided near one of the four corners of rectangular substrate 10, but the present disclosure is not limited thereto. The shape, size, and arrangement position of gate electrode pad 51 are not particularly limited.

Gate wiring portion 52 is a conductive portion that is provided above substrate 10 and electrically connects gate electrode pad 51 and gate electrode 32. Specifically, gate wiring portion 52 is electrically connected to gate electrode 32 via a plurality of gate fingers 53. In the present exemplary embodiment, gate wiring portion 52 extends from gate electrode pad 51 along the gate width direction (y-axis direction). As illustrated in FIG. 4, the wiring width of gate wiring portion 52 is a length in the x-axis direction and is represented by W1.

As illustrated in FIG. 1, the plurality of gate fingers 53 extends along the gate length direction (x-axis direction) from a long side of gate wiring portion 52. The plurality of gate fingers 53 is provided side by side at equal intervals along the y-axis direction. Note that one gate finger 53 extends from gate electrode pad 51. Each of the plurality of gate fingers 53 is electrically connected to gate electrode 32 via a through hole penetrating interlayer insulating film 40. Note that the number of gate fingers 53 may be one. Alternatively, gate finger 53 may not be provided. Gate wiring portion 52 may be provided so as to extend in the x-axis direction, and gate wiring portion 52 and gate electrode 32 may be connected via a conductive via (not illustrated).

In the present exemplary embodiment, gate wiring portion 52 is integrally formed with gate electrode pad 51 and each of the plurality of gate fingers 53. For example, gate wiring portion 52, gate electrode pad 51, and the plurality of gate fingers 53 are formed using the same material in the same process. For example, gate electrode pad 51, gate wiring portion 52, and the plurality of gate fingers 53 are metal films including a metal such as Pd, Ag, or Au as a main component. Gate electrode pad 51, gate wiring portion 52, and the plurality of gate fingers 53 are formed by, for example, plating. Alternatively, gate electrode pad 51, gate wiring portion 52, and the plurality of gate fingers 53 may be formed by forming a metal film by sputtering, vapor deposition, or the like, and then patterning the metal film into a predetermined shape by etching, lift-off, or the like. Note that gate electrode pad 51, gate wiring portion 52, and the plurality of gate fingers 53 may be formed in different steps. For example, in a case where interlayer insulating film 40 has a stacked structure of a plurality of insulating films, at least one of gate electrode pad 51, gate wiring portion 52, and the plurality of gate fingers 53 may be formed on a different insulating film among the plurality of insulating films.

Source wiring 54 is electrically connected to the plurality of source electrodes 34. Source wiring 54 also serves as a source electrode pad and is a conductive portion that receives power to be supplied to source electrode 34 from the outside of nitride semiconductor device 1. A bonding wire (not illustrated) or the like is connected to source wiring 54.

In the present exemplary embodiment, source wiring 54 includes a plurality of plate-shaped portions 54A and connection portion 54B in plain view.

Each of the plurality of plate-shaped portions 54A has a rectangular shape elongated in the gate length direction (x-axis direction). The plurality of plate-shaped portions 54A is alternately disposed along the gate width direction (y-axis direction) one by one with the plurality of gate fingers 53. The plurality of plate-shaped portions 54A is disposed apart from any of gate electrode pad 51, gate wiring portion 52, and the plurality of gate fingers 53, and is electrically separated.

Each of the plurality of plate-shaped portions 54A is connected to source electrode 34 at an intersection with source electrode 34. Specifically, as illustrated in FIG. 3, plate-shaped portion 54A and source electrode 34 are in contact with each other and electrically connected to each other through a through hole penetrating interlayer insulating film 40. Note that the number of plate-shaped portions 54A may be one.

Connection portion 54B is connected to an end portion on the positive side of the x-axis of each of the plurality of plate-shaped portions 54A. Connection portion 54B has a rectangular shape elongated in the y-axis direction, and end portions of the plurality of plate-shaped portions 54A are connected to a long side of the connection portion.

The plurality of plate-shaped portions 54A and connection portion 54B are integrally formed. For example, the plurality of plate-shaped portions 54A and connection portion 54B are formed by the same process using the same material. Source wiring 54 can be formed in the same process as at least one of gate electrode pad 51, gate wiring portion 52, and the plurality of gate fingers 53. For example, the plurality of plate-shaped portions 54A and connection portion 54B are metal films including a metal such as Pd, Ag, or Au as a main component. The plurality of plate-shaped portions 54A and connection portion 54B are formed by plating, for example. Alternatively, the plurality of plate-shaped portions 54A and connection portion 54B may be formed by forming a metal film by sputtering, vapor deposition, or the like, and then patterning the metal film into a predetermined shape by etching, lift-off, or the like. Note that the plurality of plate-shaped portions 54A and connection portion 54B may be formed in different steps. For example, in a case where interlayer insulating film 40 has a stacked structure of a plurality of insulating films, at least one of the pluralities of plate-shaped portions 54A and connection portion 54B may be formed on a different insulating film among the plurality of insulating films.

Conductive film 38 is provided between drain electrode 36 and at least one of gate electrode pad 51 and gate wiring portion 52. In the present exemplary embodiment, conductive film 38 is provided between drain electrode 36 and each of gate electrode pad 51 and gate wiring portion 52. As illustrated in FIG. 2, conductive film 38 is annularly provided so as to surround active region 2.

As illustrated in FIGS. 4 and 5, conductive film 38 is provided on block layer 14 in peripheral region 3. That is, conductive film 38 is provided in contact with upper surface 14a of block layer 14. Note that conductive film 38 may be provided inside interlayer insulating film 40.

Conductive film 38 is a metal film including metal as a main component. The metal included in conductive film 38 as a main component is one selected from the group consisting of Ti, Al, Ni, Pd, Pt, Au, and Cr. Conductive film 38 may have a single-layer structure of a metal film or a laminated structure.

In peripheral region 3, gate electrode pad 51 and gate wiring portion 52 face drain electrode 36 provided below substrate 10 with substrate 10 and the like interposed therebetween, and parasitic capacitance Cgd between the gate and the drain is generated. In the present exemplary embodiment, since conductive film 38 is provided, electric field lines extending from drain electrode 36 can be shielded by conductive film 38, so that parasitic capacitance Cgd can be reduced.

The thickness of conductive film 38 is, for example, 100nm or more and 500nm or less. As the thickness of conductive film 38 increases, the shielding effect of the electric field lines can be enhanced.

As illustrated in FIG. 4, length W2 of a portion of conductive film 38 located between gate wiring portion 52 and drain electrode 36 in the wiring width direction (x-axis direction) of gate wiring portion 52 is longer than wiring width W1 of gate wiring portion 52 in plain view of substrate 10. Since gate wiring portion 52 and drain electrode 36 can be prevented from facing each other without conductive film 38 interposed therebetween, parasitic capacitance Cgd can be reduced.

Furthermore, a portion of conductive film 38 located between gate electrode pad 51 and drain electrode 36 is formed so as to protrude from gate electrode pad 51 in plain view. Briefly, a part of conductive film 38 is formed slightly larger than gate electrode pad 51. Therefore, gate electrode pad 51 and drain electrode 36 can be prevented from facing each other without conductive film 38 interposed therebetween, so that parasitic capacitance Cgd can be reduced.

Conductive film 38 is electrically connected to source electrode 34. Specifically, as illustrated in FIG. 5, conductive film 38 is electrically connected to source wiring 54 via conductive via 39. Accordingly, the same potential (for example, 0V) is applied to conductive film 38 and source electrode 34. Therefore, the shielding effect of the electric field lines can be enhanced.

Note that conductive via 39 is a conductive portion that electrically connects source wiring 54 and conductive film 38 and is provided so as to penetrate interlayer insulating film 40. Conductive via 39 includes a metal such as Pd, Ag, or Au as a main component. Conductive via 39 may be formed integrally with source wiring 54. In the example illustrated in FIG. 2, conductive via 39 is provided in an L shape along two adjacent sides of rectangular annular conductive film 38. Note that the shape of conductive via 39 is not particularly limited, and a plurality of the conductive vias may be provided.

As described above, in nitride semiconductor device 1, since conductive film 38 is provided between gate electrode pad 51 and gate wiring portion 52, and drain electrode 36, electric field lines extending from drain electrode 36 can be shielded by conductive film 38. Therefore, parasitic capacitance Cgd between the gate and the drain can be reduced.

A manufacturing method of nitride semiconductor device 1 is not particularly limited, but for example, the following manufacturing method can be used.

First, a nitride semiconductor is crystal-grown by epitaxial growth on the principal surface of substrate 10 to form a plurality of nitride semiconductor films. Specifically, drift layer 12, block layer 14, and base layer 16 are formed in this order on the principal surface of substrate 10. The epitaxial growth is performed by, for example, metal organic chemical vapor deposition (MOCVD) or the like. In the epitaxial growth, the composition, thickness, conductivity type, impurity concentration, and the like of each of the nitride semiconductor films can be adjusted by adjusting growth conditions such as a raw material, a growth temperature, and a growth time. Note that the formation of base layer 16 may be omitted.

Thereafter, a part of each of base layer 16 and block layer 14 is removed to form first opening 20. For example, base layer 16 and block layer 14 are removed by photolithography, dry etching, or the like. At this time, by removing a part of a surface layer portion of drift layer 12 continuously from the removal of block layer 14, bottom surface 20a of first opening 20 is formed below the interface between block layer 14 and drift layer 12 as illustrated in FIG. 3.

Next, a nitride semiconductor is crystal-grown by second epitaxial growth so as to cover bottom surface 20a and side surface 20b of first opening 20 and above block layer 14 (specifically, the upper surface of base layer 16). Specifically, electron transit layer 22, electron supply layer 24, and threshold value adjustment layer 28 are formed in this order. Similarly to the first crystal growth, the composition, thickness, conductivity type, impurity concentration, and the like of the nitride semiconductor film can be adjusted by adjusting growth conditions such as a raw material, a growth temperature, and a growth time.

Next, by removing a part of each of threshold value adjustment layer 28, electron supply layer 24, electron transit layer 22, and base layer 16, second opening 30 is formed in active region 2, and upper surface 14a of block layer 14 is exposed in peripheral region 3. For example, each layer is removed by photolithography, dry etching, or the like. At this time, a part of the surface layer portion of block layer 14 may be removed continuously from the removal of base layer 16. In this case, bottom surface 30a of second opening 30 is formed below the interface between block layer 14 and base layer 16. Further, by removing a part of threshold value adjustment layer 28, threshold value adjustment layer 28 is patterned into a predetermined shape. Therefore, a portion of the upper surface of electron supply layer 24 in the vicinity of second opening 30 is exposed without being covered with threshold value adjustment layer 28.

Next, gate electrode 32 and source electrode 34 are formed in active region 2, and conductive film 38 is formed in peripheral region 3. For example, first, a conductive film is formed using a conductive material to be ohmic-connected to an n-type nitride semiconductor, and then the conductive film is patterned into a predetermined shape to form source electrode 34. The conductive film is formed by sputtering, vapor deposition, or the like. Patterning of the conductive film is performed by etching, a lift-off method, or the like. Source electrode 34 is formed so as to contact and cover bottom surface 30a and side surface 30b of second opening 30 and not to contact threshold value adjustment layer 28. Next, a conductive film is formed using a conductive material ohmic-connected to a p-type nitride semiconductor and then patterned into a predetermined shape to form gate electrode 32 and conductive film 38. Formation and patterning of the conductive film are the same as in the case of source electrode 34. Gate electrode 32 is formed on the upper surface of threshold value adjustment layer 28 so as not to contact the upper surface of electron supply layer 24 and source electrode 34. Conductive film 38 is formed on block layer 14 in peripheral region 3. Note that, although gate electrode 32 and conductive film 38 are formed in the same step, they may be formed in different steps.

Next, interlayer insulating film 40 is formed. Interlayer insulating film 40 is formed by a plasma chemical vapor deposition (CVD) method, an atomic layer deposition (ALD) method, a coating method, or the like. By etching interlayer insulating film 40 after the film formation, at least a part of each of gate electrode 32, source electrode 34, and conductive film 38 is exposed. Thereafter, gate electrode pad 51, gate wiring portion 52, the plurality of gate fingers 53, conductive via 39, and source wiring 54 are formed by a plating method or the like.

Next, drain electrode 36 is formed on the lower surface of substrate 10. For example, drain electrode 36 is formed by forming a conductive film using a conductive material to be ohmic-connected to an n-type nitride semiconductor. The conductive film is formed by sputtering, vapor deposition, or the like.

Through the above processes, nitride semiconductor device 1 illustrated in FIG. 1 can be manufactured.

### Second Exemplary Embodiment

Subsequently, a second exemplary embodiment will be described.

The second exemplary embodiment is different from the first exemplary embodiment mainly in the configuration of the gate electrode in the active region. Hereinafter, differences from the first exemplary embodiment will be mainly described, and description of common points will be omitted or simplified.

FIG. 6 is a cross-sectional view of nitride semiconductor device 101 according to the present exemplary embodiment. Specifically, FIG. 6 corresponds to a cross section taken along line III-III illustrated in FIGS. 1 and 2, and represents a cross section of active region 2 of nitride semiconductor device 101. Note that the planar layout of nitride semiconductor device 101 is the same as the planar layout of nitride semiconductor device 1 illustrated in FIGS. 1 and 2. Furthermore, the cross-sectional structure in peripheral region 3 of nitride semiconductor device 101 is the same as the cross-sectional structure of nitride semiconductor device 1 illustrated in FIGS. 4 and 5. That is, nitride semiconductor device 101 includes conductive film 38 provided in peripheral region 3.

As compared with nitride semiconductor device 1 illustrated in FIG. 3, nitride semiconductor device 101 illustrated in FIG. 6 includes electron supply layer 124, shielding layer 127, threshold value adjustment layer 128, shielding electrode 131, and gate electrode 132 instead of electron supply layer 24, threshold value adjustment layer 28, and gate electrode 32. Threshold value adjustment layer 128 and gate electrode 132 are provided on both left and right sides of first opening 20.

Electron supply layer 124 has substantially the same configuration as electron supply layer 24 but is different in that recess 126 is provided. Recess 126 is provided on both left and right sides of first opening 20.

Recess 126 is provided at a position overlapping block layer 14 in planar view of substrate 10. Note that a part or all of recess 126 may overlap side surface 20b of first opening 20 in plain view of substrate 10. Recess 126 is a recess recessed from the upper surface of electron supply layer 124 toward substrate 10. A side surface of recess 126 is perpendicular to the principal surface of substrate 10 but may be inclined obliquely.

In the present exemplary embodiment, threshold value adjustment layer 128 is provided so as to cover recess 126. In a portion where recess 126 is provided, the thickness of electron supply layer 124 is reduced. As illustrated in FIG. 6, the thickness of the portion of electron supply layer 124 where recess 126 is provided is thinner than the thickness of a portion where recess 126 is not provided.

As the thickness of the portion where recess 126 is provided decreases, the concentration of 2DEG 23 in a direction immediately below recess 126 decreases. Therefore, a threshold value of the transistor can be increased. For example, the threshold value can be made higher than 0V, which facilitates normally-off of the transistor. By adjusting the thickness of the portion where recess 126 is provided, the threshold value of the transistor can be determined. For example, the thickness of the portion where recess 126 is provided is 10nm or more and 60nm or less, and is, as an example, 20nm.

Furthermore, the portion of electron supply layer 124 where recess 126 is not provided can be thickened without affecting the threshold value of the transistor. For example, the portion where recess 126 is not provided has a thickness of 10nm or more and 70nm or less, and is, as an example, 65nm. By thickening the portion where recess 126 is not provided, the concentration of 2DEG 23 increases, so that the on resistance can be reduced. By providing recess 126 in this manner, it is possible to achieve both the normally-off and the reduction in the on-resistance.

Note that recess 126 is formed by removing a part of electron supply layer 124 after forming electron supply layer 124 and before forming threshold value adjustment layer 128. Electron supply layer 124 is removed by etching.

Shielding layer 127 is an example of a p-type fourth nitride semiconductor layer and is provided between shielding electrode 131 and electron supply layer 124. Shielding layer 127 overlaps bottom surface 20a and side surface 20b of first opening 20 in plain view of substrate 10. Shielding layer 127 is provided in contact with each of the upper surface of electron supply layer 124 and the lower surface of shielding electrode 131. Shielding layer 127 is electrically connected to shielding electrode 131.

Threshold value adjustment layer 128 is an example of a p-type third nitride semiconductor layer and is provided between gate electrode 132 and electron supply layer 124. Threshold value adjustment layer 128 is provided between source electrode 34 and shielding layer 127 spaced apart from both source electrode 34 and shielding layer 127. Threshold value adjustment layer 128 is electrically separated from both source electrode 34 and shielding layer 127. Threshold value adjustment layer 128 is electrically connected to gate electrode 132.

=In the present exemplary embodiment, threshold value adjustment layer 128 is provided so as to contact and cover at least a part of the bottom surface of recess 126. Specifically, threshold value adjustment layer 128 is provided so as to cover a bottom surface and a side surface of recess 126 and a portion outside recess 126. That is, the length of threshold value adjustment layer 128 in the gate length direction is longer than the length of recess 126 in the gate length direction.

Shielding layer 127 and threshold value adjustment layer 128 are formed by removing and separating a part of the nitride semiconductor film formed in the same step. Thus, shielding layer 127 and threshold value adjustment layer 128 have the same composition, thickness, carrier concentration, and the like. For example, each of shielding layer 127 and threshold value adjustment layer 128 is a film having a thickness of 200nm, having a carrier concentration of 5 × 10¹⁷ cm⁻³ and including p-type GaN as a main component.

Shielding electrode 131 is provided above shielding layer 127 at a position overlapping first opening 20 in plain view of substrate 10. Shielding electrode 131 is electrically connected to source electrode 34 and shielding layer 127. Specifically, source wiring 54 is connected to shielding electrode 131, and is set to the same potential as source electrode 34.

=Gate electrode 132 is provided above threshold value adjustment layer 128. Gate electrode 132 is provided at a position overlapping block layer 14 without overlapping first opening 20 in plain view of substrate 10. Specifically, gate electrode 132 is provided in contact with the upper surface of threshold value adjustment layer 128.

Shielding electrode 131 and gate electrode 132 are formed by removing and separating a part of the conductive film formed in the same step. Accordingly, the main components of shielding electrode 131 and gate electrode 132 are the same. For example, each of shielding electrode 131 and gate electrode 132 includes, as a main component, a material that is ohmic-connected to a p-type nitride semiconductor such as p-type GaN. For example, Pd, a Ni-based material, WSi, Au, or the like can be used as a material for forming shielding electrode 131 and gate electrode 132.

According to nitride semiconductor device 101 of the present exemplary embodiment, the threshold value of the transistor is determined by the flat portion of the channel outside first opening 20 and is not affected by the inclined portion of the channel. Therefore, controllability of On and Off of the transistor can be enhanced. Furthermore, by providing shielding electrode 131 electrically connected to source electrode 34, shielding electrode 131 can terminate the electric field lines extending from drain electrode 36. Parasitic capacitance Cgd between the gate and the drain can be reduced, and the switching speed can be increased.

Furthermore, a source potential is supplied from shielding electrode 131 to shielding layer 127. Therefore, a reverse bias can be applied to the pn junction between shielding layer 127 and 2DEG 23 via shielding electrode 131 and drain electrode 36. Therefore, the withstand voltage of nitride semiconductor device 101 can be increased.

Furthermore, the structure of peripheral region 3 is the same as that of nitride semiconductor device 1 according to the first exemplary embodiment, and conductive film 38 is provided. Accordingly, similarly to the first exemplary embodiment, by providing conductive film 38 between gate electrode pad 51 and gate wiring portion 52, and drain electrode 36, electric field lines extending from drain electrode 36 can be shielded by conductive film 38. Therefore, parasitic capacitance Cgd between the gate and the drain can be reduced.

Note that nitride semiconductor device 101 according to the present exemplary embodiment may include electron supply layer 24 according to the first exemplary embodiment instead of electron supply layer 124. That is, recess 126 may not be provided.

Furthermore, recess 126 may be provided in nitride semiconductor device 1 according to the first exemplary embodiment. That is, nitride semiconductor device 1 according to the first exemplary embodiment may include electron supply layer 124 provided with recess 126 instead of electron supply layer 24. In this case, threshold value adjustment layer 28 may cover at least a part of the bottom surface of recess 126 in contact therewith.

### Other Exemplary Embodiments

Although the nitride semiconductor device according to one or a plurality of aspects has been described on the basis of the exemplary embodiments, the present disclosure is not limited to these exemplary embodiments. Configurations in which various modifications conceivable by those skilled in the art are applied to the present exemplary embodiments and forms constructed by combining constituent elements in different exemplary embodiments are also included in the scope of the present disclosure without departing from the gist of the present disclosure.

For example, conductive film 38 may be provided between gate electrode pad 51 and drain electrode 36 and may not be provided between gate wiring portion 52 and drain electrode 36. Alternatively, conductive film 38 may be provided between gate wiring portion 52 and drain electrode 36 and may not be provided between gate electrode pad 51 and drain electrode 36. Furthermore, wiring width W1 of gate wiring portion 52 may be longer than width W2 of conductive film 38. In any case, electric field lines can be shielded as compared with a case where conductive film 38 is not provided, and parasitic capacitance Cgd can be reduced.

Furthermore, for example, second opening 30 may not be provided. In this case, source electrode 34 is provided on the upper surface of electron supply layer 24 and is electrically connected to 2DEG 23 via electron supply layer 24.

For example, in nitride semiconductor devices 1 and 101 according to the exemplary embodiments, a high-resistance layer having a higher resistance than block layer 14 may be provided between drift layer 12 and block layer 14. The high-resistance layer is, for example, a nitride semiconductor layer including carbon-doped GaN (C-GaN) as a main component. The carbon concentration of the high-resistance layer is, for example, more than or equal to 3 × 10¹⁷ cm⁻³, but may be more than or equal to 1 × 10¹⁸ cm⁻³. The high-resistance layer is provided in contact with each of drift layer 12 and block layer 14. The high-resistance layer may include an n-type impurity such as Si. The concentration of the n-type impurities included in the high-resistance layer is lower than the carbon concentration and the oxygen concentration of the high-resistance layer, and may be, for example, 5 × 10¹⁶ cm⁻³ or less, or 2 × 10¹⁶ cm⁻³ or less. By providing the high-resistance layer, punch-through can be suppressed, and the withstand voltage can be increased. Note that, in a case where the high-resistance layer is formed, first opening 20 penetrates the high-resistance layer. Therefore, since the high-resistance layer is not located on the path of the drain current when the transistor is ON, an increase in the on-resistance can be suppressed.

Furthermore, for example, drift layer 12 may have a graded structure in which the impurity concentration (donor concentration) gradually decreases from a substrate 10 side toward block layer 14 side. Note that the donor concentration may be controlled by Si as a donor or may be controlled by carbon as an acceptor that compensates for Si. Alternatively, drift layer 12 may have a stacked structure of a plurality of nitride semiconductor layers having different impurity concentrations. Specifically, the drift layer is formed into two layers, a layer having a low donor concentration is disposed below the block layer, and a layer having a high donor concentration is disposed further below the block layer (that is, on the substrate side). Then, by providing first opening 20 so as to penetrate the layer having a low donor concentration, a current flows through the layer having a high donor concentration through first opening 20 when the transistor is ON, so that on resistance can be reduced. On the other hand, when the transistor is OFF, a high electric field is held by the layer having a low donor concentration, and thus, both low on-resistance and high withstand voltage can be achieved.

For example, threshold value adjustment layer 28 or 128 may cover only a part of the bottom surface of recess 126 in contact with the bottom surface. That is, the bottom surface of recess 126 may be provided with a portion covered with interlayer insulating film 40 without being covered with threshold value adjustment layer 28 or 128. For example, an end portion of threshold value adjustment layer 28 or 128 on a side of source electrode 34 may be located on the bottom surface of recess 126. In this case, 2DEG 23 is not generated when OFF in a direction immediately below the bottom surface of recess 126 located closer to the side of source electrode 34 than threshold value adjustment layer 28 or 128. Therefore, since an area in which threshold value adjustment layer 28 or 128 electrically connected to gate electrode 32 and 2DEG 23 face each other is reduced, capacitance Cgs between the gate and the source can be reduced.

Note that not only the end portion of threshold value adjustment layer 128 on the side of source electrode 34 but also the end portion on the opposite side thereof may be located on the bottom surface of recess 126. That is, threshold value adjustment layer 128 may be provided so as not to contact the side surface of recess 126. Also in this case, since an area where threshold value adjustment layer 128 and 2DEG 23 face each other is reduced, capacitance Cgs between the gate and the source can be reduced.

Furthermore, the side surface of recess 126 on the side of source electrode 34 may not be provided, and the bottom surface of recess 126 may extend to immediately below source electrode 34. That is, a part of source electrode 34 may contact and cover a part of the bottom surface of recess 126.

For each of the exemplary embodiments described above, various changes, replacements, additions, omissions, and the like can be made within the scope of claims or equivalents thereof.

According to the present disclosure, the parasitic capacitance between the gate and the drain can be reduced.

The nitride semiconductor device according to the present disclosure is useful as, for example, a power device used in a power supply circuit, an inverter circuit, or the like of an electric device.

What is claimed is:

1. A nitride semiconductor device comprising:
a substrate;
a gate electrode disposed above the substrate in a first region in plan view of the substrate;
a drain electrode disposed below the substrate;
a gate electrode pad disposed above the substrate in a second region that does not overlap with the first region in plan view of the substrate;
a gate wiring portion disposed above the substrate and electrically connecting the gate electrode pad and the gate electrode; and
a conductive film disposed between the drain electrode and at least one of the gate electrode pad and the gate wiring portion.

2. The nitride semiconductor device according to claim 1, further comprising:
a first nitride semiconductor layer of a first conductivity type disposed above the substrate;
a second nitride semiconductor layer of a second conductivity type disposed above the first nitride semiconductor layer, the second conductivity type being opposite in polarity to the first conductivity type;
an electron transit layer and an electron supply layer disposed in order from a side of the substrate, the electron transit layer and the electron supply layer covering an inner surface of a first opening that penetrates the second nitride semiconductor layer and reaches the first nitride semiconductor layer and an upper portion of the second nitride semiconductor layer; and
a source electrode electrically connected to the electron transit layer,
wherein the gate electrode is disposed above the electron supply layer.

3. The nitride semiconductor device according to claim 2, wherein
the conductive film is disposed on the second nitride semiconductor layer.

4. The nitride semiconductor device according to claim 2, wherein
the conductive film is electrically connected to the source electrode.

5. The nitride semiconductor device according to claim 1, wherein
the conductive film has a length in a wiring width direction of the gate wiring portion, the length being a length of a portion of the conductive film located between the gate wiring portion and the drain electrode, and being longer than a wiring width of the gate wiring portion in plan view of the substrate.

6. The nitride semiconductor device according to claim 1, wherein
the conductive film includes a metal film including a metal as a main component.

7. The nitride semiconductor device according to claim 6, wherein
the metal is one selected from a group consisting of Ti, Al, Ni, Pd, Pt, Au, and Cr.

8. The nitride semiconductor device according to claim 2, wherein
the gate electrode is disposed at a position overlapping the first opening in plan view of the substrate.

9. The nitride semiconductor device according to claim 2, further comprising
a shielding electrode disposed at a position overlapping the first opening in plan view of the substrate and electrically connected to the source electrode,
wherein the gate electrode is disposed at a position overlapping the second nitride semiconductor layer without overlapping the first opening in plan view of the substrate.

10. The nitride semiconductor device according to claim 2, further comprising
a third nitride semiconductor layer of the second conductivity type disposed between the electron supply layer and the gate electrode.
